(19) United States
(12) Patent Application Publication
(10) Pub. No.: US 2026/0293627 A1
(43) Pub. Date: Sep. 24, 2026

(54) SUBSTRATE ISOLATION IN A THREE DIMENSIONAL (3D) MEMORY ARRAY

(71) Applicant: Micron Technology, Inc., Boise, ID (US)

(72) Inventors: Pavani Vamsi Krishna Nittala, Meridian, ID (US); Sok Han Wong, Boise, ID (US); Adharsh Rajagopal, Meridian, ID (US); Kolya Yastrebenetsky, Boise, ID (US); David A. Daycock, Boise, ID (US)

(21) Appl. No.: 19/566,169

(22) Filed: Mar. 13, 2026

Related U.S. Application Data
(60) Provisional application No. 63/774,570, filed on Mar. 19, 2025.

(51) Int. Cl. H10W 10/10; H10P 72/70; H10P 90/00; H10B 12/00; H10D 62/83; H10D 62/832

(52) U.S. Cl. CPC H10W 10/181; H10P 72/744; H10P 90/1914; H10B 12/03; H10B 12/05; H10B 12/30; H10D 62/83; H10D 62/832

(57) ABSTRACT

Systems, methods, and apparatus are provided for substrate isolation in a three-dimensional (3D) memory array. A 3D memory device can include a substrate, an isolation layer on the substrate, a vertical stack on the isolation layer, and a vertical opening through the vertical stack to the isolation layer.

### PRIORITY INFORMATION

This Application claims the benefit of U.S. Provisional Application Number 63/774,570, filed on Mar. 19, 2025, the contents of which are incorporated herein by reference.

### TECHNICAL FIELD

The present disclosure relates generally to memory devices, and more particularly, to substrate isolation in a 3D memory array.

### BACKGROUND

Memory is often implemented in electronic systems, such as computers, cell phones, hand-held devices, etc. There are many different types of memory, including volatile and non-volatile memory. Volatile memory may require power to maintain its data and may include random-access memory (RAM), dynamic random-access memory (DRAM), static random-access memory (SRAM), and synchronous dynamic random-access memory (SDRAM). Non-volatile memory may provide persistent data by retaining stored data when not powered and may include NAND flash memory, NOR flash memory, nitride read only memory (NROM), phase-change memory (e.g., phase-change random access memory), resistive memory (e.g., resistive random-access memory), cross-point memory, ferroelectric random-access memory (FeRAM), or the like.

As design rules shrink, less semiconductor space is available to fabricate memory, including DRAM arrays. A respective memory cell for DRAM may include an access device, e.g., transistor, having a first and a second source/drain region separated by a channel region. A gate may oppose the channel region and be separated therefrom by a gate dielectric. An access line, such as a word line, is electrically connected to the gate of the DRAM memory cell. A DRAM memory cell can include a storage node, such as a capacitor cell, coupled by the access device to a sense line, such as a digit line. The access device can be activated (e.g., to select the cell) by an access line coupled to the access device. The capacitor can store a charge corresponding to a data value of a respective memory cell (e.g., a logic “1” or “0”).

### BRIEF DESCRIPTION OF THE DRAWINGS

FIGS. 1A-1F illustrate an example method, at one stage of a semiconductor fabrication process, for isolating substrate in three dimensional (3D) arrays of vertically stacked memory cells, having horizontally oriented access devices and storage nodes, in accordance with a number of embodiments of the present disclosure.

FIGS. 2A-2C is a perspective view illustrating an example method, at one stage of a semiconductor fabrication process, for isolating substrate in three dimensional (3D) arrays of vertically stacked memory cells, having horizontally oriented access devices and storage nodes, in accordance with a number of embodiments of the present disclosure.

FIG. 3 is a cross-sectional view of a vertical stack in vertical three dimensional (3D) memory in accordance with a number of embodiments of the present disclosure.

FIGS. 4A-4B illustrate an example method, at one stage of a semiconductor fabrication process, for isolating substrate in three dimensional (3D) arrays of vertically stacked memory cells, having horizontally oriented access devices and storage nodes, in accordance with a number of embodiments of the present disclosure.

FIGS. 5A-5D illustrate an example method, at one stage of a semiconductor fabrication process, for isolating substrate in three dimensional (3D) arrays of vertically stacked memory cells, having horizontally oriented access devices and storage nodes, in accordance with a number of embodiments of the present disclosure.

FIGS. 6A-6B illustrate an example method, at one stage of a semiconductor fabrication process, for isolating substrate in three dimensional (3D) arrays of vertically stacked memory cells, having horizontally oriented access devices and storage nodes, in accordance with a number of embodiments of the present disclosure.

FIGS. 7A-7B illustrate an example method, at one stage of a semiconductor fabrication process, for isolating substrate in three dimensional (3D) arrays of vertically stacked memory cells, having horizontally oriented access devices and storage nodes, in accordance with a number of embodiments of the present disclosure.

FIGS. 8A-8C illustrate an example method, at one stage of a semiconductor fabrication process, for isolating substrate in three dimensional (3D) arrays of vertically stacked memory cells, having horizontally oriented access devices and storage nodes, in accordance with a number of embodiments of the present disclosure.

FIG. 9 is a block diagram of an apparatus in the form of a computing system including a memory device in accordance with a number of embodiments of the present disclosure.

### DETAILED DESCRIPTION

Embodiments of the present disclosure describe substrate isolation in a three dimensional (3D) memory array. A 3D memory device can include a substrate, an isolation layer on the substrate, a vertical stack on the isolation layer, and a vertical opening through the vertical stack to the isolation layer. The isolation layer can be formed using a wafer-to-wafer bonding. In a number of embodiments, an etch stop layer can be formed on the isolation layer using the wafer-to-wafer bonding.

In some previous approaches, 3D memory arrays of vertically stacked memory cells are connected to a substrate. Isolating a 3D array of vertically stacked memory cells from a substrate, as disclosed herein, can reduce current leakage through the substrate and helps control other losses from radio frequency (RF) and analog coupling.

With increasing number of tiers in 3D memory arrays, the complexity of the fabrication process increases. For example, the greater number of tiers in 3D memory arrays, the higher the risk of failing substrate isolation at the higher number of tiers. This makes it difficult to predict the cost of fabrication and the reliability of the 3D memory array.

The present method of wafer-to-wafer bonding for substrate isolation in a 3D memory array can be used for 3D DRAM and other DRAM technologies including, but not limited to, vertical channel transistors. The present method can be used for substrate isolation for any number of tiers. Further, the cost is fixed for any number of tiers.

The substrate isolation described herein can act as an etch stop layer for all deep dry etches involved in the 3D DRAM flow. This can enhance the dry etch process stability and can help in reducing process variation.

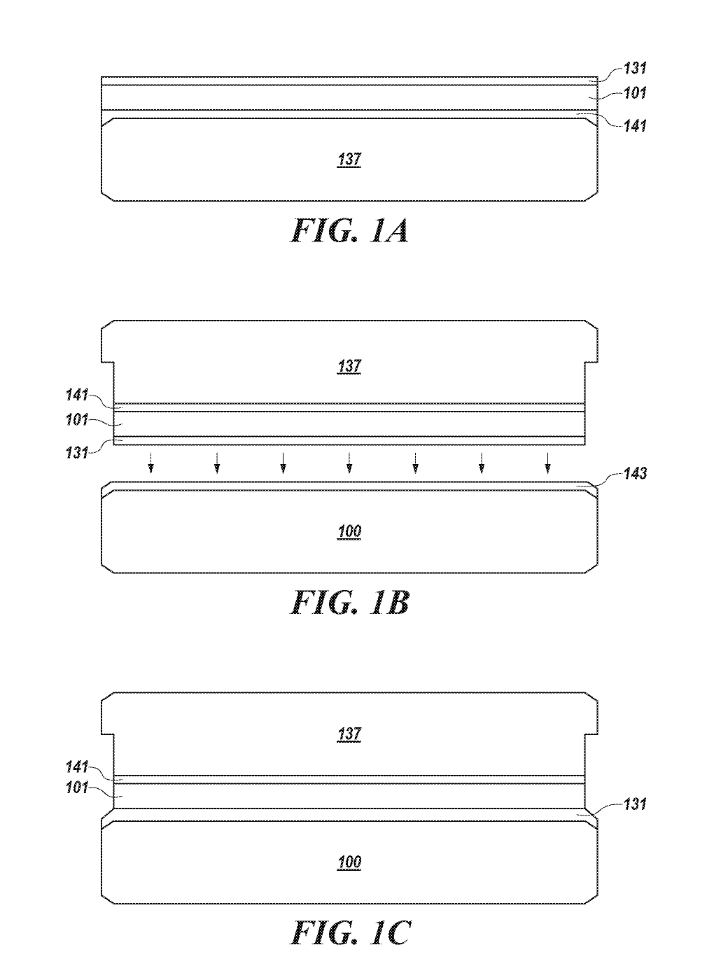

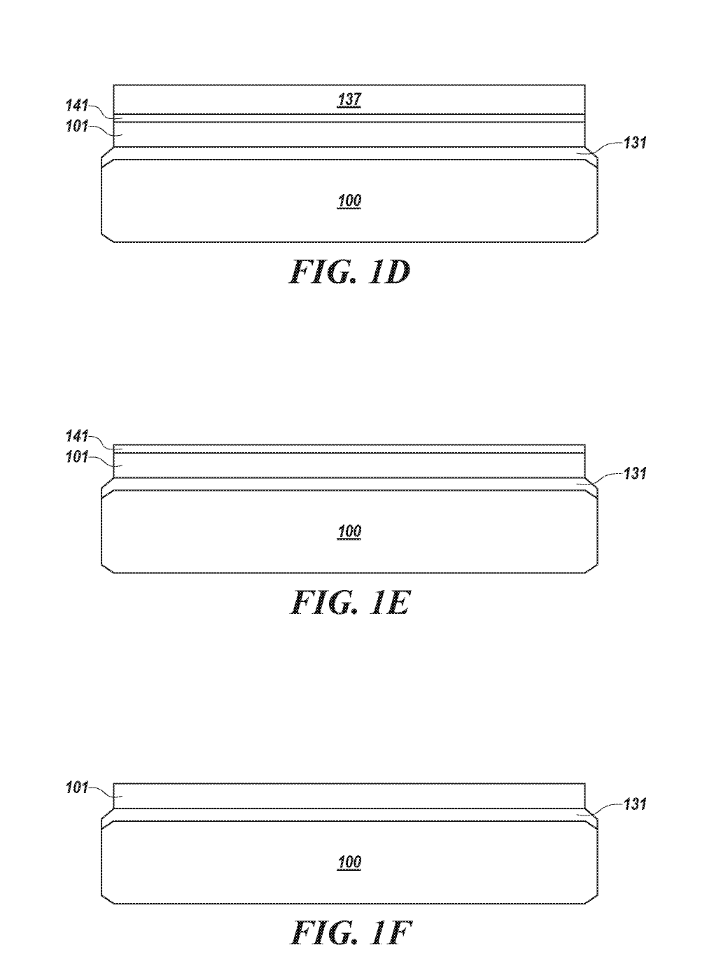

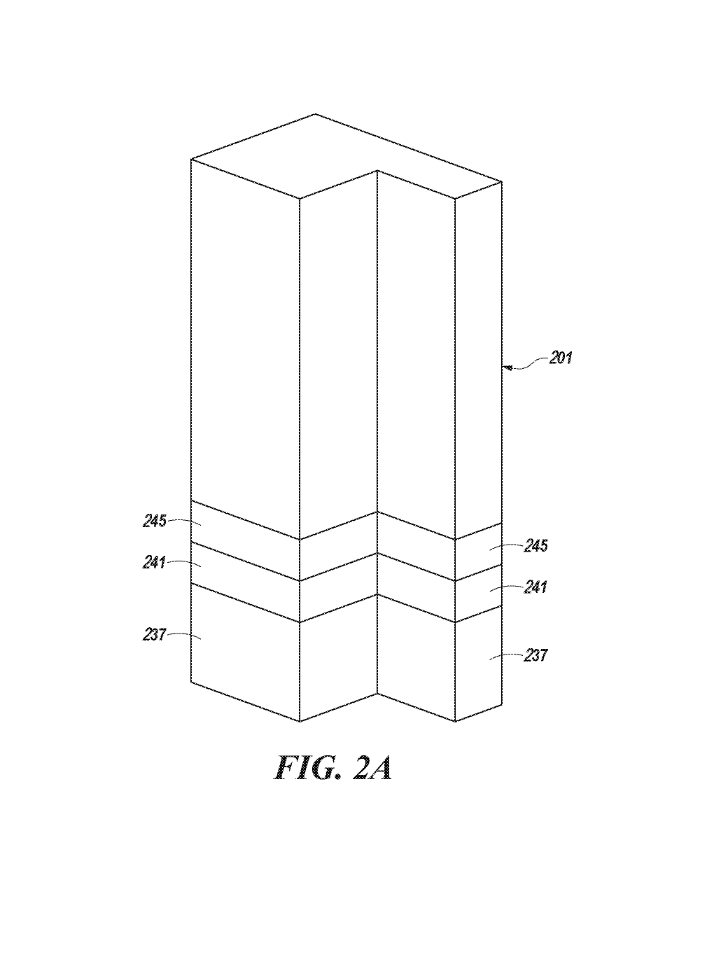

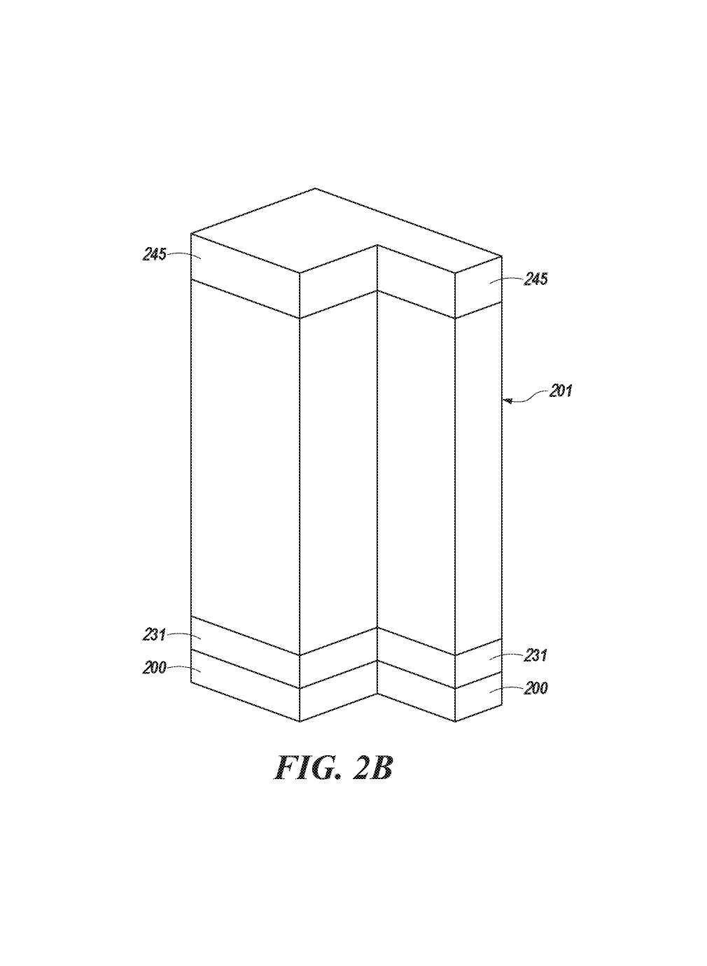

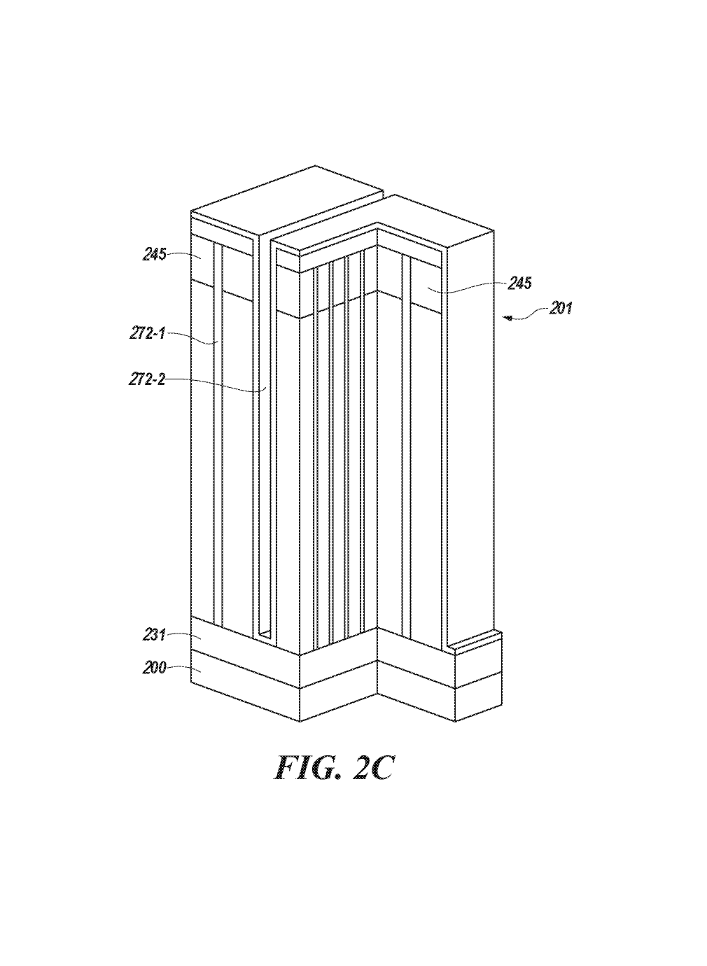

The figures herein follow a numbering convention in which the first digit or digits correspond to the figure number of the drawing and the remaining digits identify an element or component in the drawing. Similar elements or components between different figures may be identified by the use of similar digits. For example, reference numeral 101 may reference element “01” in FIG. 1A, and a similar element may be referenced as 201 in FIG. 2A.

Multiple analogous elements within one figure may be referenced with a reference numeral followed by a hyphen and another numeral or a letter. For example, 330-1 may reference element 330-1 in FIG. 3 and 330-2 may reference element 330-2, which may be analogous to element 330-1. Such analogous elements may be generally referenced without the hyphen and extra numeral or letter. For example, elements 330-1 and 330-2 or other analogous elements may be generally referenced as 330.

FIG. 1A illustrates an example method, at one stage of a semiconductor fabrication process, for isolating substrate in three dimensional (3D) arrays of vertically stacked memory cells, having horizontally oriented access devices and storage nodes, in accordance with a number of embodiments of the present disclosure. A 3D array can comprise a plurality of layers.

The method can include forming an etch stop layer 141 from a sacrificial substrate 137 to start fabrication of a first wafer for 3D DRAM, as illustrated in FIG. 1A. The sacrificial substrate 137 can include silicon and the etch stop layer 141 can include silicon germanium carbon material, silicon germanium material, silicon carbon material, silicon phosphorus material, and/or silicon boron material, for example.

Alternating layers of silicon germanium material and silicon material from the etch stop layer 141 can form a vertical stack 101 of the first wafer. The alternating layers can be included in the plurality of layers of the 3D array. In some examples, the vertical stack 101 can be formed by alternating layers of epitaxial material and silicon material from the etch stop layer 141.

As illustrated in FIG. 1A, the method can further include forming an isolation layer 131 from the vertical stack 101. In some examples, the isolation layer 131 can be formed using wafer-to-wafer bonding and a part of the etch stop layer 141 can be formed on the isolation layer 131 using the wafer-to-wafer bonding. The isolation layer 131 can include an oxide material, an oxide nitride material, a dielectric bond material, and/or a dielectric copper material.

FIG. 1B illustrates an example method, at one stage of a semiconductor fabrication process, for isolating substrate in three dimensional (3D) arrays of vertically stacked memory cells, having horizontally oriented access devices and storage nodes, in accordance with a number of embodiments of the present disclosure.

The method can include forming a bonding layer 143 from a substrate 100, as illustrated in FIG. 1B. The substrate 100 and the bonding layer 143 can be included in a second wafer. The second wafer can be referred to herein as a blank wafer.

FIG. 1C illustrates an example method, at one stage of a semiconductor fabrication process, for isolating substrate in three dimensional (3D) arrays of vertically stacked memory cells, having horizontally oriented access devices and storage nodes, in accordance with a number of embodiments of the present disclosure.

The method can include bonding the isolation layer 131 with the bonding layer (e.g., bonding layer 143 of FIG. 1B), as illustrated in FIG. 1C. For example, the first wafer can be rotated (e.g., flipped) such that the isolation layer 131 contacts the bonding layer of the second wafer. Bonding the isolation layer 131 to the bonding layer couples (e.g., bonds) the first wafer to the second wafer via wafer-to-wafer bonding.

The isolation layer 131 and the bonding layer can include a bonding oxide. Oxide based fusion bonding can be used to bond the isolation layer 131 with the bonding layer. The isolation layer 131 can isolate the horizontally orientated access devices (e.g., access devices) from the substrate 100.

FIG. 1D illustrates an example method, at one stage of a semiconductor fabrication process, for isolating substrate in three dimensional (3D) arrays of vertically stacked memory cells, having horizontally oriented access devices and storage nodes, in accordance with a number of embodiments of the present disclosure.

The method can include removing the sacrificial substrate 137, as illustrated in FIG. 1D. At least a portion of the sacrificial substrate 137 can be removed by grinding.

FIG. 1E illustrates an example method, at one stage of a semiconductor fabrication process, for isolating substrate in three dimensional (3D) arrays of vertically stacked memory cells, having horizontally oriented access devices and storage nodes, in accordance with a number of embodiments of the present disclosure.

The method can include removing sacrificial substrate (e.g., sacrificial substrate 137 of FIGS. 1A, 1B, 1C and 1D), as illustrated in FIG. 1E. At least a portion of the sacrificial substrate can be removed by etching. For example, the sacrificial substrate can be thinned to a few microns by back grinding followed by etching.

FIG. 1F illustrates an example method, at one stage of a semiconductor fabrication process, for isolating substrate in three dimensional (3D) arrays of vertically stacked memory cells, having horizontally oriented access devices and storage nodes, in accordance with a number of embodiments of the present disclosure.

The method can include removing an etch stop layer (e.g., etch stop layer 141 of FIGS. 1A, 1B, 1C, 1D and 1E). At least a portion of the etch stop layer can be removed by etching. The etch stop layer can help with total thickness variation in the sacrificial substrate removal process.

The vertical stack 101, the isolation layer 131, and the substrate 100 can remain, as illustrated in FIG. 1F. The isolation layer 131 can improve possible variation in the process flow. For example, dry etch depths can be made uniform with the isolation layer 131 and electrically isolate access devices.

FIG. 2A is a perspective view illustrating an example method, at one stage of a semiconductor fabrication process, for isolating substrate in three dimensional (3D) arrays of vertically stacked memory cells, having horizontally oriented access devices and storage nodes, in accordance with a number of embodiments of the present disclosure.

The method can include forming an etch stop layer 241 from a sacrificial substrate 237. The sacrificial substrate 237 can include silicon and the etch stop layer 241 can include silicon germanium carbon material, silicon germanium material, silicon carbon material, silicon phosphorus material, and/or silicon boron material, for example.

In a number of embodiments, a multiplexor silicon layer 245 can be formed from the etch stop layer 241. The vertical stack 201 can be formed from the multiplexor silicon layer 245 and comprise a plurality of layers including alternating layers of silicon germanium material and silicon material, for example.

FIG. 2B is a perspective view illustrating an example method, at one stage of a semiconductor fabrication process, for isolating substrate in three dimensional (3D) arrays of vertically stacked memory cells, having horizontally oriented access devices and storage nodes, in accordance with a number of embodiments of the present disclosure.

The method can include bonding a first wafer with a second wafer. The first wafer can include a sacrificial substrate (e.g., sacrificial substrate 237 of FIG. 2A), an etch stop layer (e.g., etch stop layer 241 of FIG. 2A), a multiplexor silicon layer 245, and a vertical stack 201 while the second wafer can include substrate 200. The first and second wafers can be bonded via an isolation layer 231, as illustrated in FIG. 2B. In some examples, oxide based fusion bonding can be used to bond the first wafer with the second wafer.

The method can further include removing the sacrificial substrate and the etch stop layer as illustrated in FIG. 2B. In some examples, the sacrificial substrate and the etch stop layer can be removed by grinding and/or etching.

FIG. 2C is a perspective view illustrating an example method, at one stage of a semiconductor fabrication process, for isolating substrate in three dimensional (3D) arrays of vertically stacked memory cells, having horizontally oriented access devices (e.g., access devices) and storage nodes, in accordance with a number of embodiments of the present disclosure.

The method can include forming a number of vertical openings 272-1 and 272-2 through a vertical stack 201, as illustrated in FIG. 2C. A portion or portions of the vertical stack 201 can be removed to create the number of vertical openings 272-1 and 272-2 through the vertical stack 201 to the isolation layer 231. The number of vertical openings 272-1 and 272-2 can land on the isolation layer 231 and can be formed by etching.

A 3D memory device, as illustrated in FIG. 2C, can include the substrate 200, the isolation layer 231 on the substrate 200, the vertical stack 201 on the isolation layer 231, and the vertical openings 272-1 and 272-2 through the vertical stack 201 to the isolation layer 231. The 3D memory device including the isolation layer 231 can isolate the access devices from the substrate 200.

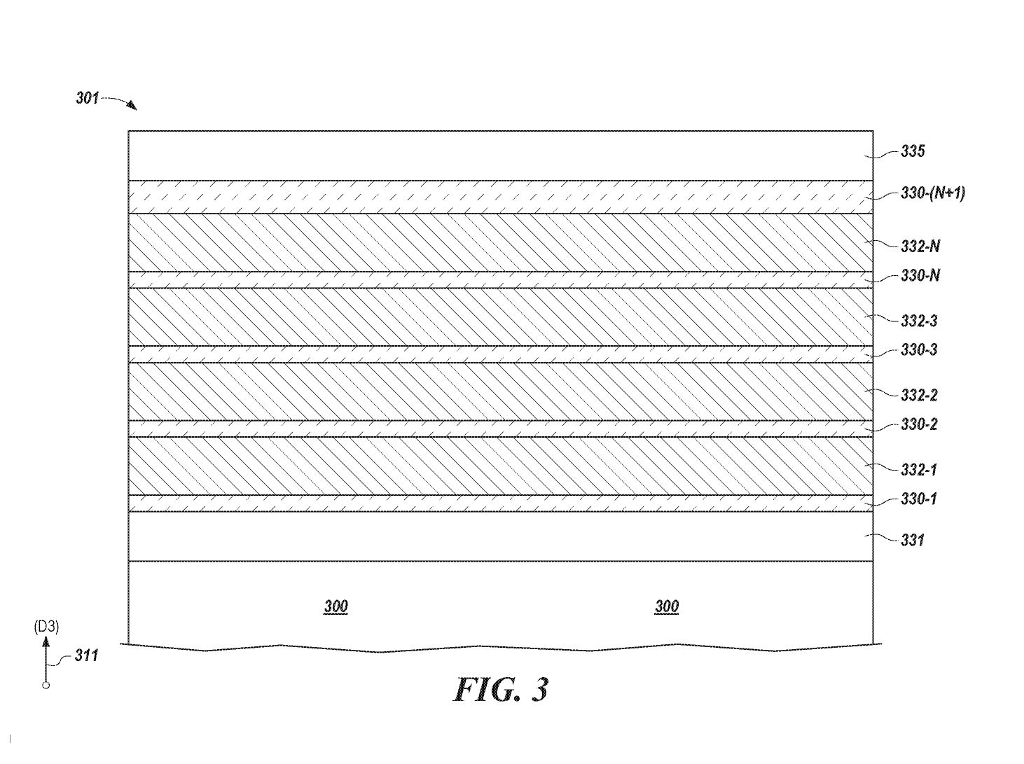

FIG. 3 is a cross-sectional view of a vertical stack in vertical three dimensional (3D) memory in accordance with a number of embodiments of the present disclosure. In the example embodiment shown in the example of FIG. 3, a method of forming the vertical stack 301 can comprise forming alternating layers of a silicon germanium (SiGe) material , 330-1, 330-2, . . ., 530-N (collectively referred to as silicon germanium (SiGe) 330), and a silicon (Si) material, 332-1, 332-2, . . ., 332-N (collectively referred to as single crystalline silicon (Si) material 332), in repeating iterations to form a vertical stack 301 and bonding the vertical stack 301 to a working surface of a substrate 300 via an isolation layer 331. In some embodiments, the silicon germanium (SiGe) material 330 and the silicon (Si) material 332 can be epitaxially grown.

In one embodiment, the silicon germanium (SiGe) 330 can be deposited to have a thickness, e.g., vertical height in the third direction (D3), in a range of five (5) nanometers to thirty (30) nm. In one embodiment, the silicon (Si) material 332 can be deposited to have a thickness (t2), e.g., vertical height, in a range of thirty (30) nanometers (nm) to sixty (60) nm. Embodiments, however, are not limited to these examples. As shown in FIG. 3, a vertical direction 311 is illustrated as a third direction (D3), e.g., z-direction in an x-y-z coordinate system.

In some embodiments, the silicon germanium (SiGe), 330-1, 330-2, . . ., 330-N, may be a mix of silicon and germanium. By way of example, and not by way of limitation, the silicon germanium (SiGe) material 330 may be bonded to the substrate 300 via the isolation layer 331. Embodiments are not limited to these examples. In some embodiments, the single crystalline silicon (Si) material, 332-1, 332-2, . . ., 332-N, may comprise a silicon (Si) material in a polycrystalline and/or amorphous state. The single crystalline silicon (Si) material, 332-1, 332-2, . . ., 332-N, may be a low doped, p-type (p-) single crystalline silicon (Si) material. The silicon (Si) material, 332-1, 332-2, . . ., 332-N, may also be formed on the silicon germanium (SiGe) 330. If the silicon germanium (SiGe) 330 was epitaxially grown, the seed is turned to pure silicon after the silicon germanium (SiGe) 330 has been formed.

The repeating iterations of alternating silicon germanium (SiGe), 330-1, 330-2, . . ., 330-N layers and single crystalline silicon (Si) material, 332-1, 332-2, . . ., 332-N layers may be deposited according to a semiconductor fabrication process such as chemical vapor deposition (CVD) in a semiconductor fabrication apparatus. Embodiments, however, are not limited to this example and other suitable semiconductor fabrication techniques may be used to deposit the alternating layers of silicon germanium (SiGe) and single crystalline silicon (Si) material, in repeating iterations to form the vertical stack 301.

The layers may occur in repeating iterations vertically. For example, the vertical stack 301 may include: a first silicon germanium (SiGe) material 330-1, a first single crystalline silicon (Si) material 332-1, a second silicon germanium (SiGe) material 330-2, a second single crystalline silicon (Si) material 332-2, a third silicon germanium (SiGe) material 330-3, and a third single crystalline silicon (Si) material 332-3, in further repeating iterations. Embodiments, however, are not limited to this example and more or fewer repeating iterations may be included. In some examples, photolithographic mask 335 may be deposited over a silicon germanium (SiGe) material 330.

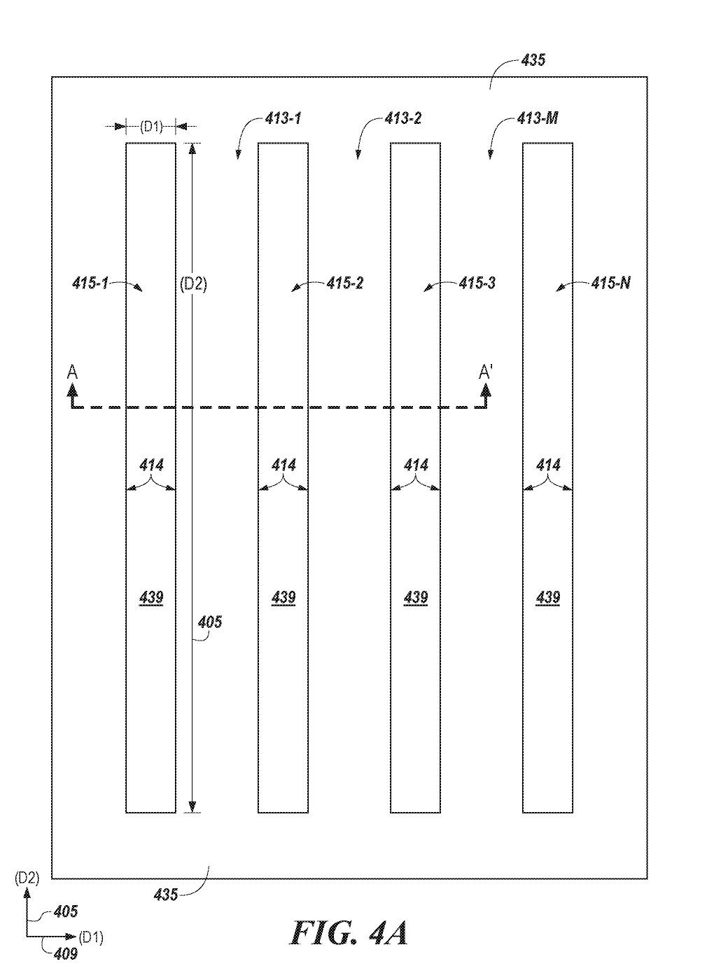

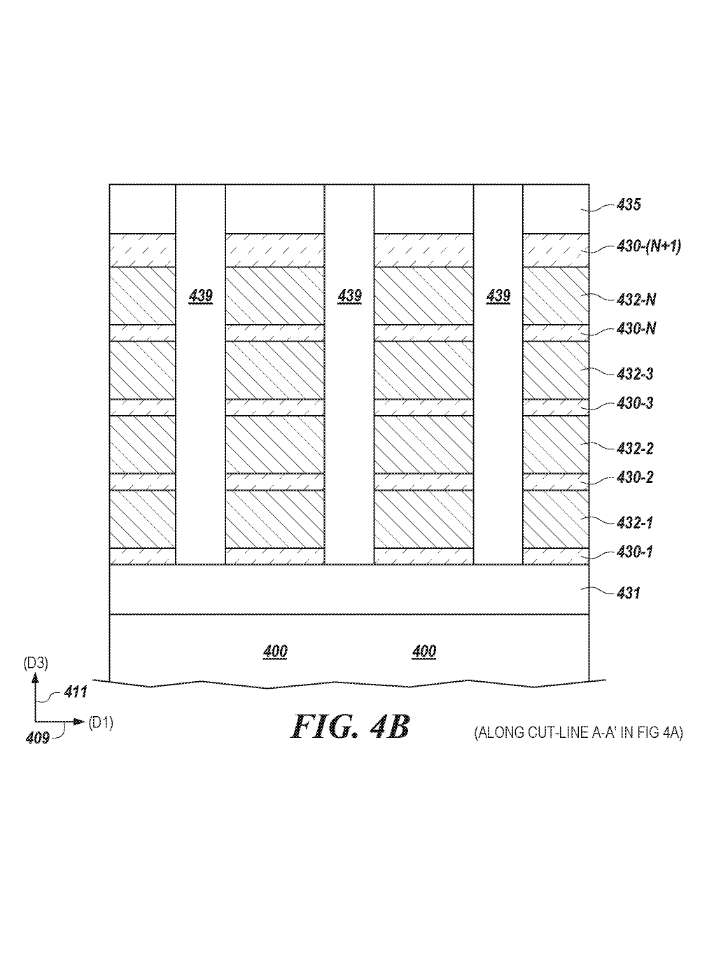

FIG. 4A illustrates an example method, at one stage of a semiconductor fabrication process, for isolating substrate in three dimensional (3D) arrays of vertically stacked memory cells, having horizontally oriented access devices and storage nodes, in accordance with a number of embodiments of the present disclosure. FIG. 4A illustrates a top down view of a semiconductor structure, at a particular point in time, in a semiconductor fabrication process, according to one or more embodiments. In the example embodiment shown in the example of FIG. 4A, the method comprises using an etching process to form a plurality of vertical openings 415-1, 415-2, 415-3, . . ., 415-N (individually or collectively referred to as vertical openings 415), having a first horizontal direction (D1) 409 and a second horizontal direction (D2) 405, through the vertical stack to the substrate. In one example, as shown in FIG. 4A, the plurality of vertical openings (e.g., four vertical openings) 415 are extending predominantly in the second horizontal direction (D2) 405 and may form elongated vertical, pillar columns 413-1, 413-2, . . ., 413-M (collectively and/or independently referred to as vertical, pillar columns 413), with sidewalls 414 in the vertical stack. The plurality of first vertical openings 415 may be formed using photolithographic techniques to pattern a photolithographic mask 435, e.g., to form a hard mask (HM), on the vertical stack prior to etching the plurality of first vertical openings 415. Similar semiconductor process techniques may be used at other points of the semiconductor fabrication process described herein.

The first vertical openings 415 may be filled with a first dielectric material (e.g., first dielectric material 439 of FIG. 4B). In one example, a spin on dielectric process may be used to fill the first vertical openings 415. In one embodiment, the first dielectric material may be an oxide material. However, embodiments are not so limited.

FIG. 4B is a cross sectional view, taken along cut-line A-A’ in FIG. 4A, showing another view of the semiconductor structure at a particular time in the semiconductor fabrication process for isolating substrate in three dimensional (3D) arrays of vertically stacked memory cells, having horizontally oriented access devices and storage nodes, in accordance with a number of embodiments of the present disclosure. The cross sectional view shown in FIG. 4B shows the repeating iterations of alternating layers of a silicon germanium (SiGe) material 430 and a single crystalline silicon (Si) material 432 on an isolation layer 431 and the isolation layer 431 on a substrate 400.

As shown in FIG. 4B, a plurality of vertical openings may be formed through the layers within the vertically stacked memory cells, stacked in a third direction (D3) 411 to expose vertical sidewalls in the vertical stack and form elongated vertical pillar columns (e.g., vertical pillar columns 413 of FIG. 4A) and then filled with a first dielectric material 439. First vertical openings (e.g., first vertical openings 415 of FIG. 4A) may be formed through the repeating iterations of the silicon germanium (SiGe) material 430 and the single crystalline silicon (Si) material 432. As such, the first vertical openings may be formed through a first silicon germanium (SiGe) material 430-1, a first single crystalline silicon (Si) material 432-1, a second silicon germanium (SiGe) material 430-2, a second single crystalline silicon (Si) material 432-2, a third silicon germanium (SiGe) material 430-3, and a third single crystalline silicon (Si) material 432-3. Embodiments, however, are not limited to the vertical opening(s) shown in FIG. 4B. Multiple vertical openings may be formed through the layers of materials. The vertical openings may be formed to expose vertical sidewalls in the vertical stack. The vertical openings may extend in a first direction (D1) 409 to form elongated vertical, pillar columns with vertical sidewalls in the vertical stack and then filled with first dielectric 439.

As shown in FIG. 4B, a first dielectric material 439, such as an oxide or other suitable spin on dielectric (SOD), may be deposited in the first vertical openings, using a process such as CVD, to fill the first vertical openings. First dielectric material 439 may also be formed from a silicon nitride (Si₃N₄) material. In another example, the first dielectric material 439 may include silicon oxy-nitride (SiOₓN_{y}), and/or combinations thereof. Embodiments are not limited to these examples. The plurality of first vertical openings may be formed using photolithographic techniques to pattern a photolithographic mask 435, e.g., to form a hard mask (HM), on the vertical stack prior to etching the plurality of first vertical openings 415. In one embodiment, hard mask 435 may be deposited over a silicon germanium (SiGe) material 430. Similar semiconductor process techniques may be used at other points of the semiconductor fabrication process described herein.

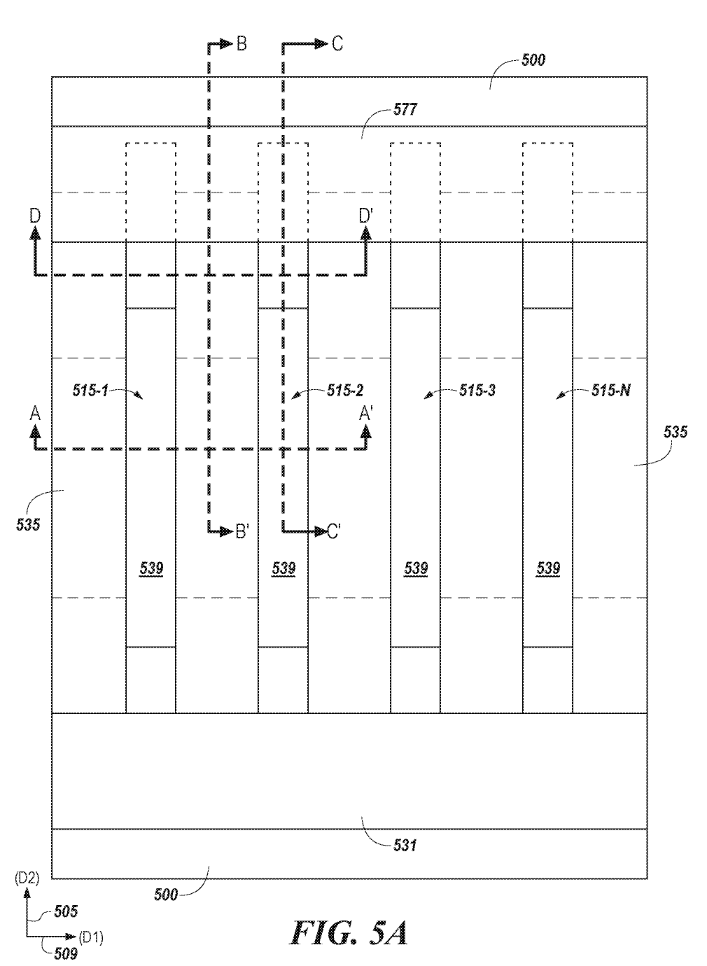

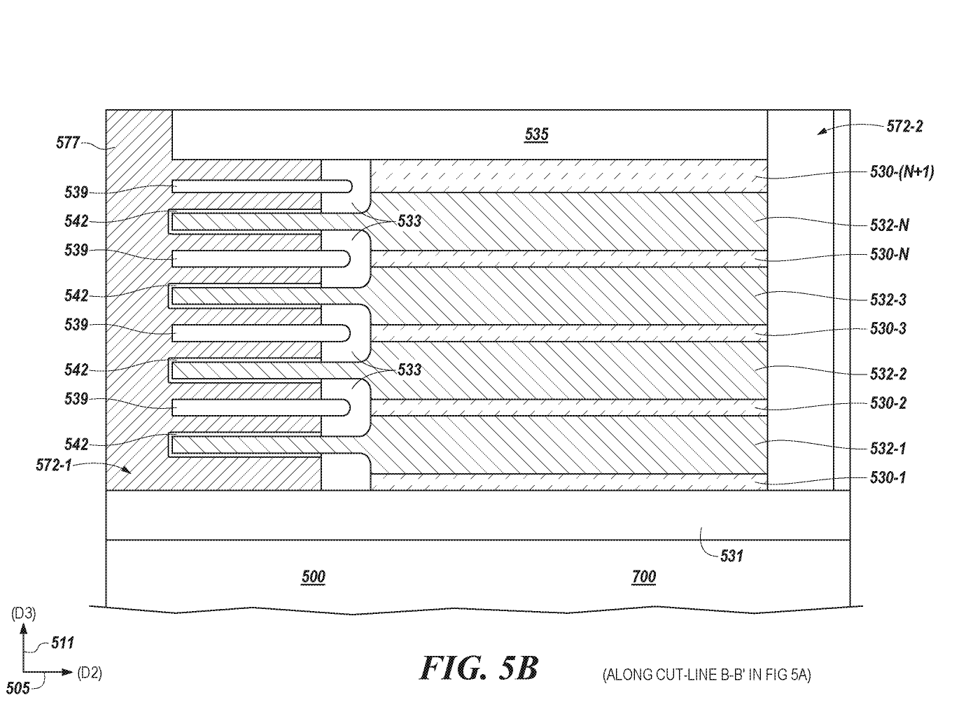

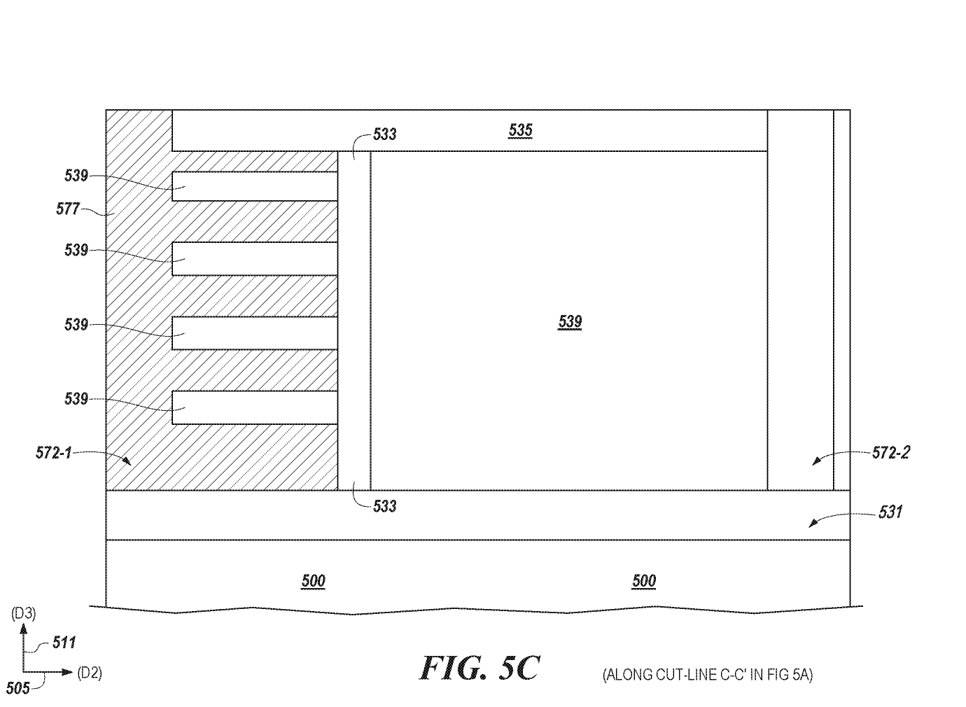

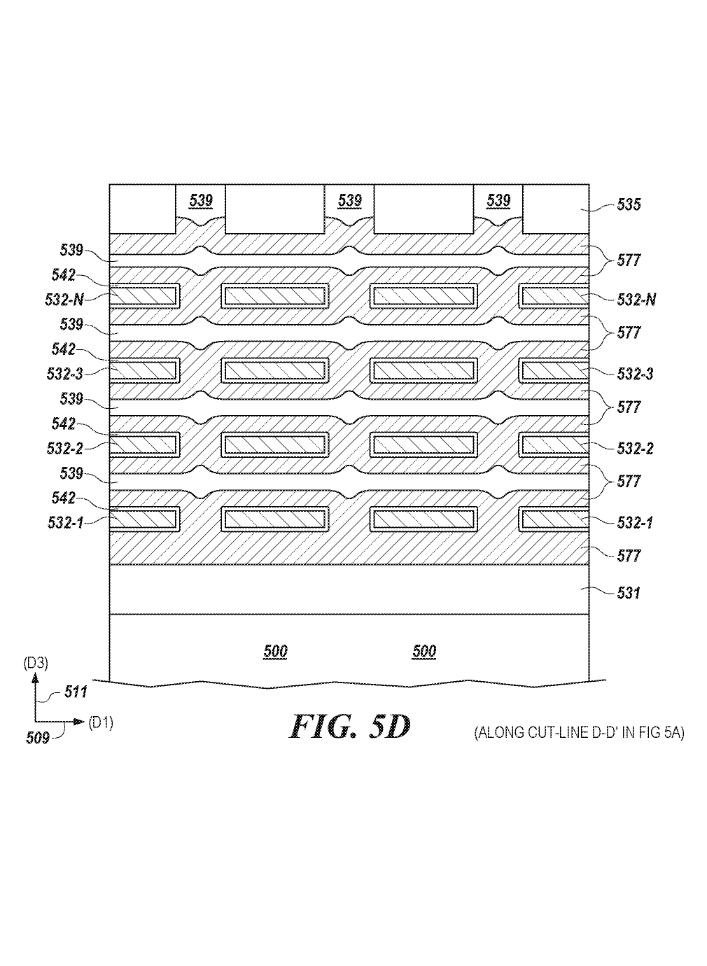

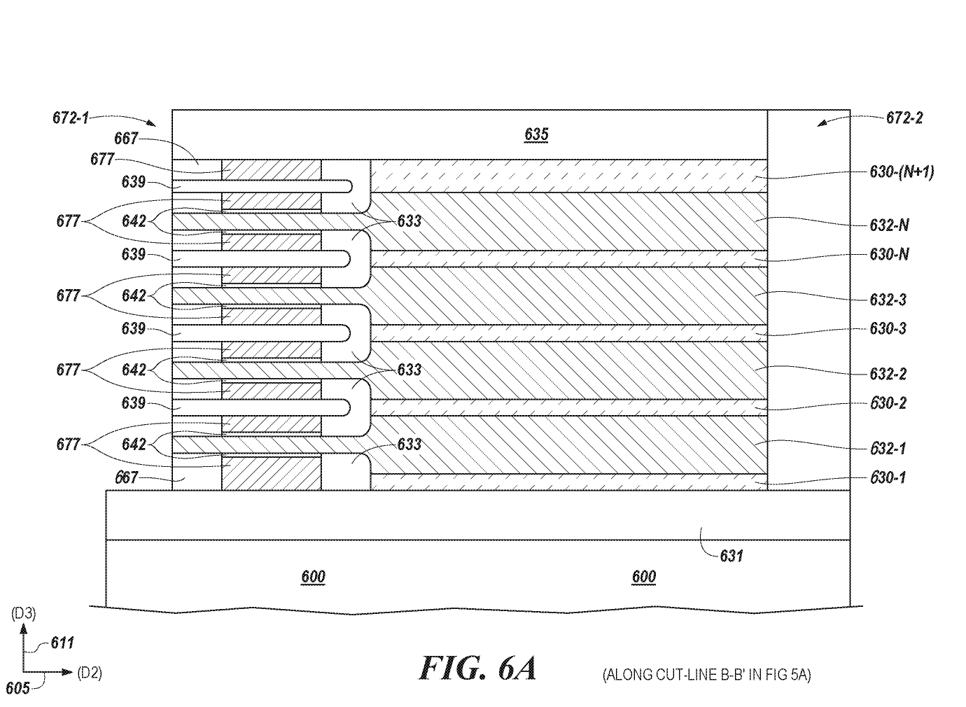

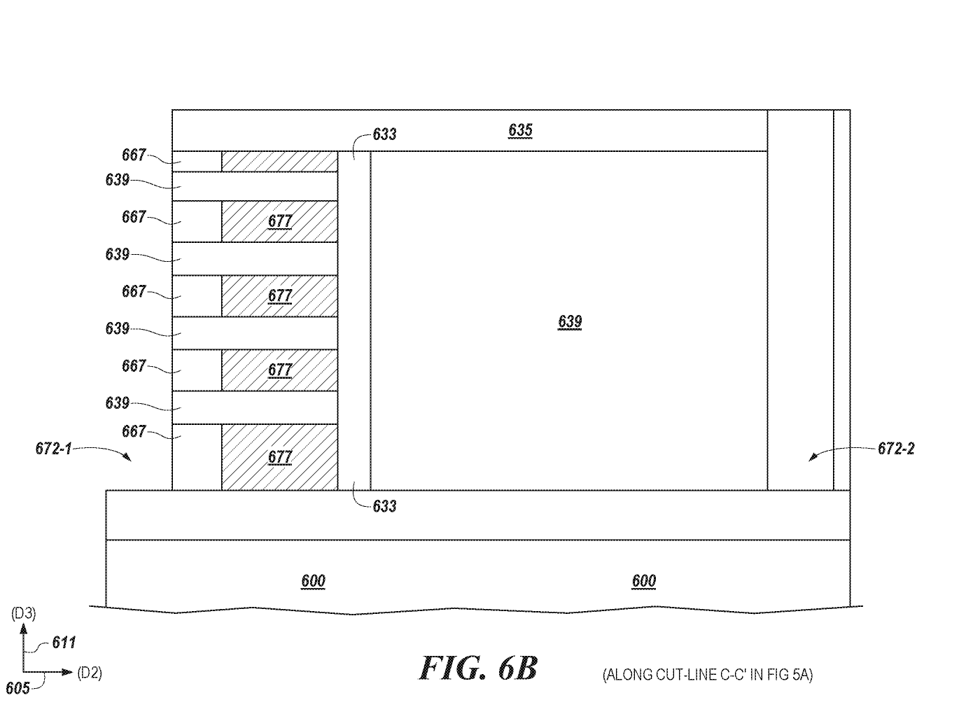

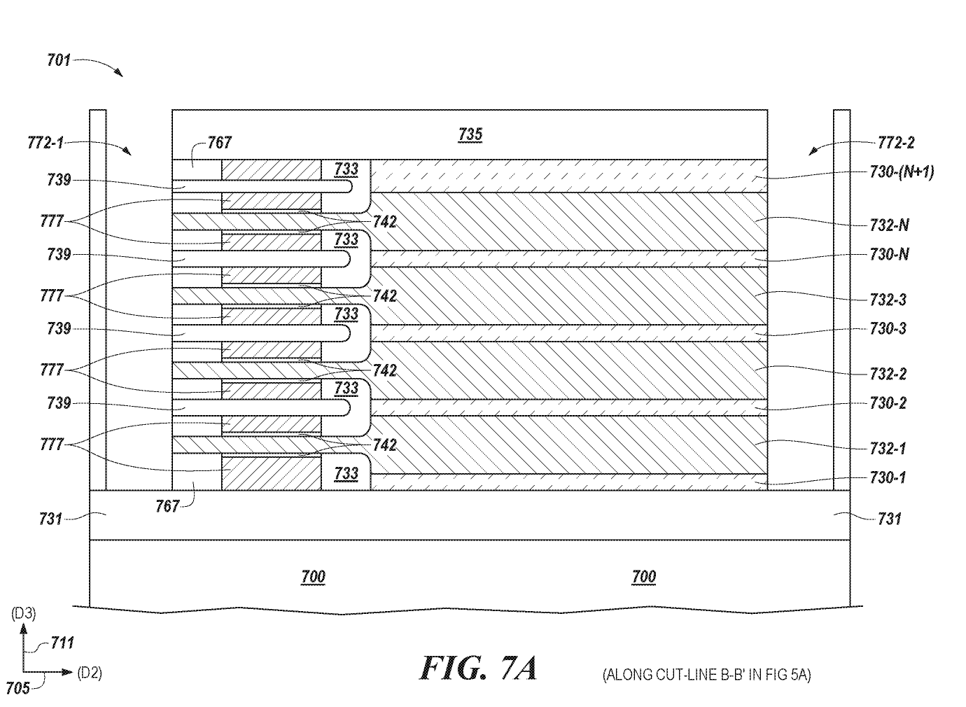

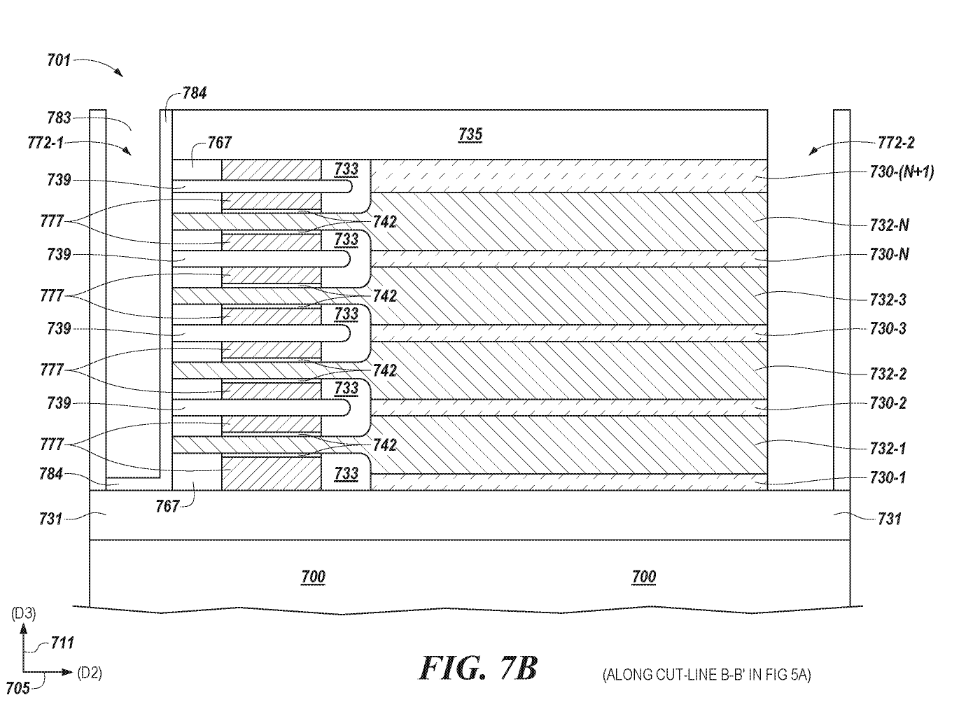

FIG. 5A illustrates an example method, at one stage of a semiconductor fabrication process, for isolating substrate in three dimensional (3D) arrays of vertically stacked memory cells, having horizontally oriented access devices and storage nodes, in accordance with a number of embodiments of the present disclosure. FIG. 5A illustrates a top down view of a semiconductor structure, at a particular point in time, in a semiconductor fabrication process, according to one or more embodiments. In the example embodiment of FIG. 5A, the method comprises using a photolithographic process to pattern the photolithographic mask 535. A first conductive material 577 may be deposited above the vertical openings 515. The first conductive material 577 may be deposited in the continuous first horizontal openings to form horizontally oriented access lines opposing channel regions of a single crystalline silicon (Si) material (e.g., single crystalline silicon (Si) material 532 of FIG. 5B).

FIG. 5B illustrates a cross sectional view, taken along cut-line B-B’ in FIG. 5A, showing another view of the semiconductor structure at this particular point in one example semiconductor fabrication process for isolating substrate in three dimensional (3D) arrays of vertically stacked memory cells, having horizontally oriented access devices and storage nodes, in accordance with a number of embodiments of the present disclosure. The cross sectional view shown in FIG. 5B is illustrated extending in the second horizontal direction (D2) 505, left and right along the plane of the drawing sheet.

A process of depositing and etching materials is used to form the structure shown in FIG. 5B. In some embodiments, the process of depositing and etching materials can include forming horizontally oriented access devices and horizontally oriented storage nodes to form an array of vertically stacked memory cells. Each of the horizontally oriented access devices can have first source/drain regions and second source/drain regions separated by channel regions. In some embodiments, gates can be formed fully around every surface of the channel regions as gate all around (GAA) structures on a gate dielectric material. Further, in some embodiments, the second source/drain regions can be coupled to storage nodes.

The semiconductor structure shown in FIG. 5B shows the semiconductor structure after the silicon germanium (SiGe) layers 530 are selectively etched to form a plurality of first horizontal openings a first length from first vertical openings 572-1. In some embodiments, the second vertical openings 572-2 can be formed to a depth in a range of 0.5 to one (1) micrometer (µm). Further, in some embodiments, each of the first vertical openings 572-1 can be formed to have an aspect ratio in a range of 15-20. In some embodiments, the selective etch that forms to plurality of second horizontal openings can also reduce a vertical thickness of the silicon (Si) layers 532. In some embodiments, a vertical thickness of a portion of each of the silicon (Si) layers 532 can be reduced to a vertical thickness in a range of 100-150 Angstroms (Å).

The process of forming the horizontally oriented access devices can further include conformally depositing a second dielectric material 533 on exposed surfaces in the plurality of first horizontal openings and depositing the first dielectric material 539 to fill the plurality of first horizontal openings. The second dielectric material 533 can be selectively etched from the plurality of first horizontal openings a second length (L2) from the first vertical opening 572-1. In some embodiments, the second length (L2) can be a length in a range of 130-170 nanometers (nm).

A first conductive material 577 may be deposited in the first horizontal opening on the gate dielectric material 542 after selectively etching the second dielectric material 533. The first conductive material 577 may be deposited around the single crystalline silicon (Si) material 532 such that the first conductive material 577 may have a top portion above the single crystalline silicon (Si) material 532 and a bottom portion below the single crystalline silicon (Si) material to form a gate all around (GAA) gate structure, at a channel of an access device region. The first conductive material 577 may be conformally deposited into vertical openings 572-1 and fill the continuous horizontal openings up to the unetched portions, the first dielectric material 539, and the second dielectric material 533. The conductive material 577 may be conformally deposited using a chemical vapor deposition (CVD) process, plasma enhanced CVD (PECVD), atomic layer deposition (ALD), or other suitable deposition process.

In some embodiments, the first conductive material, 577, may comprise one or more of a doped semiconductor, e.g., doped silicon, doped germanium, etc., a conductive metal nitride, e.g., titanium nitride, tantalum nitride, etc., a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc., and/or some other combination thereof. The first conductive material 577 entwined with the gate dielectric material 542 may form horizontally oriented access lines opposing a channel region of the single crystalline silicon (Si) material (which also may be referred to as word lines).

FIG. 5C illustrates a cross sectional view, taken along cut-line C-C’ in FIG. 5A, showing another view of the semiconductor structure at this particular point in one example semiconductor fabrication process of an embodiment of the present disclosure. The cross sectional view shown in FIG. 5C is illustrated extending in the second horizontal direction (D2) 505, left and right in the plane of the drawing sheet, along an axis of the repeating iterations of alternating layers of continuous horizontal openings and single crystalline silicon (Si) material (e.g., single crystalline silicon (Si) material 532 of FIG. 5B).

In FIG. 5C, first dielectric material 539 is shown spaced along a second horizontal direction (D2) 505, extending into and out from the plane of the drawings sheet, for a three dimensional (3D) array of vertically oriented memory cells, which can include vertical openings 572-1 and 572-2. At the left end of the drawing sheet is shown horizontal openings filled with a first conductive material 577. The first conductive material 577 may be conformally deposited into vertical openings 572-1 and into the horizontal openings. The first conductive material 577 is formed on the gate dielectric material (e.g., gate dielectric material 542 in FIG. 5B). At the right hand of the drawing sheet, the first dielectric material 539 may be seen, separating access device and storage node regions, and having the horizontal opening filled with the second dielectric material 533 and the first dielectric material 539.

FIG. 5D illustrates a cross sectional view, taken along cut-line D-D’ in FIG. 5A, showing another view of the semiconductor structure at this particular point in one example semiconductor fabrication process for isolating substrate in three dimensional (3D) arrays of vertically stacked memory cells, having horizontally oriented access devices and storage nodes, in accordance with a number of embodiments of the present disclosure. The cross sectional view shown in FIG. 5D is illustrated, right to left in the plane of the drawing sheet, extending in the first direction (D1) 509 along an axis of the repeating iterations of alternating layers of first dielectric material 539 and single crystalline silicon (Si) material 532 wrapped with a gate dielectric material 542. The gate dielectric material 542 may be conformally deposited fully around every surface of the single crystalline silicon (Si) material 532, to form gate all around (GAA) gate structures, at the channels of the access device regions. The first conductive material 577 may fill the spaces adjacent the bridged single crystalline silicon (Si) material 532. The single crystalline silicon (Si) material 532 may be surrounded by the first conductive material 577 formed on the gate dielectric material 542. The first conductive material 577 may be conformally deposited fully around every surface of the single crystalline silicon (Si) material 532, to form gate all around (GAA) gate structures, at the channels of the access device regions. In FIG. 5D, the first conductive material, 577 is shown filling in the space in the second horizontal openings left by the etched second dielectric material (e.g., etched second dielectric material 533 of FIG. 5C).

FIG. 6A illustrates an example method, at another stage of a semiconductor fabrication process, for isolating substrate in three dimensional (3D) arrays of vertically stacked memory cells, having horizontally oriented access devices and storage nodes, in accordance with a number of embodiments of the present disclosure. The cross sectional view shown in FIG. 6A is illustrated extending in the second horizontal direction (D2) 605, left and right along the plane of the drawing sheet, along an axis of the repeating iterations of alternating layers of the silicon germanium (SiGe) material 630 and the single crystalline silicon (Si) material 632.

A first conductive material 677 was deposited on the gate dielectric material 642 and formed around the single crystalline silicon (Si) material 632, recessed back, to form gate all around (GAA) structure opposing channel regions of the single crystalline silicon (Si) material 632. The first conductive material 677, formed on the gate dielectric material 642, may be recessed and etched away from the vertical opening 672-1. In some embodiments, the first conductive material 677 may be etched using an atomic layer etching (ALE) process. In some embodiments, the first conductive material 677 may be etched using an isotropic etch process. The first conductive material 677 may be selectively etched leaving the oxide material 642 covering the epitaxially grown, single crystalline silicon (Si) material and the first dielectric material 642 intact. The first conductive material 677 may be selectively etched in the second direction, in the continuous horizontal openings, a third distance (DIST 3) in a range of twenty (20) to fifty (50) nanometers (nm) back from the first vertical opening 672-1. The first conductive material 677 may be selectively etched around the single crystalline silicon (Si) material 632 back into the continuous horizontal openings extending in the first horizontal direction.

An interlayer dielectric (ILD) fill material 667 can be deposited on the gate dielectric material 642 and formed around the single crystalline silicon (Si) material 632. Horizontal access devices of a vertical 3D memory array can include the first dielectric material 639, the second dielectric material 633, the first conductive material 677, and the ILD fill material 667.

FIG. 6B illustrates an example method, at one stage of a semiconductor fabrication process, for isolating substrate in three dimensional (3D) arrays of vertically stacked memory cells, having horizontally oriented access devices and storage nodes, in accordance with a number of embodiments of the present disclosure. The cross sectional view shown in FIG. 6B is illustrated extending in the second direction (D2) 605, left and right in the plane of the drawing sheet, along an axis of the repeating iterations of alternating layers of the etched first conductive material 677 and single crystalline silicon (Si) material (e.g., single crystalline silicon (Si) material 632 of FIG. 6A).

In FIG. 6B, first dielectric material 639 is shown spaced along a first horizontal direction extending into and out from the plane of the drawings sheet, for a three dimensional (3D) array of vertically oriented memory cells. At the left end of the drawing sheet is shown the first conductive material 677 formed on gate dielectric material (e.g., gate dielectric material 642 of FIG. 6A) was etched away from the vertical opening 672-1. The first conductive material 677, formed on the gate dielectric material, is also recessed back in the continuous horizontal openings extending in the first horizontal direction. The first conductive material 677 may be selectively etched leaving the oxide material covering the single crystalline silicon (Si) material intact. In some embodiments, the first conductive material 677 may be etched using an atomic layer etching (ALE) process. In some embodiments, the first conductive material 677 may be etched using an isotropic etch process.

FIGS. 7A-7B illustrate an example method, at one stage of a semiconductor fabrication process, for isolating substrate 700 in three dimensional (3D) arrays of vertically stacked memory cells, having horizontally oriented access devices and storage nodes, in accordance with a number of embodiments of the present disclosure. The substrate 700 can be isolated by having an isolation layer 731 between the substrate 700 and the vertical stack 701 including alternating layers of SiGe material 730 and Si material 732 followed by a photolithographic mask 735.

As illustrated in FIG. 7A, a method for isolating the substrate 700 can include forming a first vertical opening 772-1 in a vertical direction 711 through the vertical stack 701 to the isolation layer 731 and extending predominantly in a first horizontal direction 705 to expose first vertical sidewalls in the vertical stack 701. The method can further include forming a second vertical opening 772-2 through the vertical stack 701 to the isolation layer 731 and extending predominantly in a second horizontal direction 705 to expose second vertical sidewalls in the vertical stack 701. In some examples, the first vertical opening 772-1 and the second vertical opening 772-2 can be formed at the same time.

A first conductive material 777 can be deposited on a gate dielectric material 742 and formed around the Si material 732, recessed back, to form GAA structure opposing channel regions of the Si material 732. The first conductive material 777, formed on the gate dielectric material 742, may be recessed and etched away from the first vertical opening 772-1. The first conductive material 777 may be selectively etched leaving the oxide material 742 covering the epitaxially grown, Si material 732 and the first dielectric material 742 intact. The first conductive material 777 may be selectively etched in the second direction, in the continuous horizontal openings. The first conductive material 777 may be selectively etched around the Si material 732 back into the continuous horizontal openings extending in the first horizontal direction.

An interlayer dielectric (ILD) fill material 767 can be deposited on the gate dielectric material 742 and formed around the Si material 732. Horizontal access devices of a vertical 3D memory array can include the first dielectric material 739, the second dielectric material 733, the first conductive material 777, and the ILD fill material 767.

As illustrated in FIG. 7B, a digit line liner 784 can be deposited in vertical opening 772-1 and on isolation layer 731. The vertical stack 701 can be isolated from the substrate 700 by separating the digit line liner 784 from the substrate 700 via the isolation layer 731.

Isolating the vertical stack 701 and the digit line liner 784 from the substrate 700 can avoid shorting. Using a wafer to wafer bonding process for isolating the vertical stack 701 and the digit line liner 784 from the substrate 700, as disclosed in FIGS. 7A-7B, can prevent the need for trench depth alignment with the first layer of the vertical stack 701 and enables the first vertical opening 772-1 and the second vertical opening 772-2 to be etched at the same time.

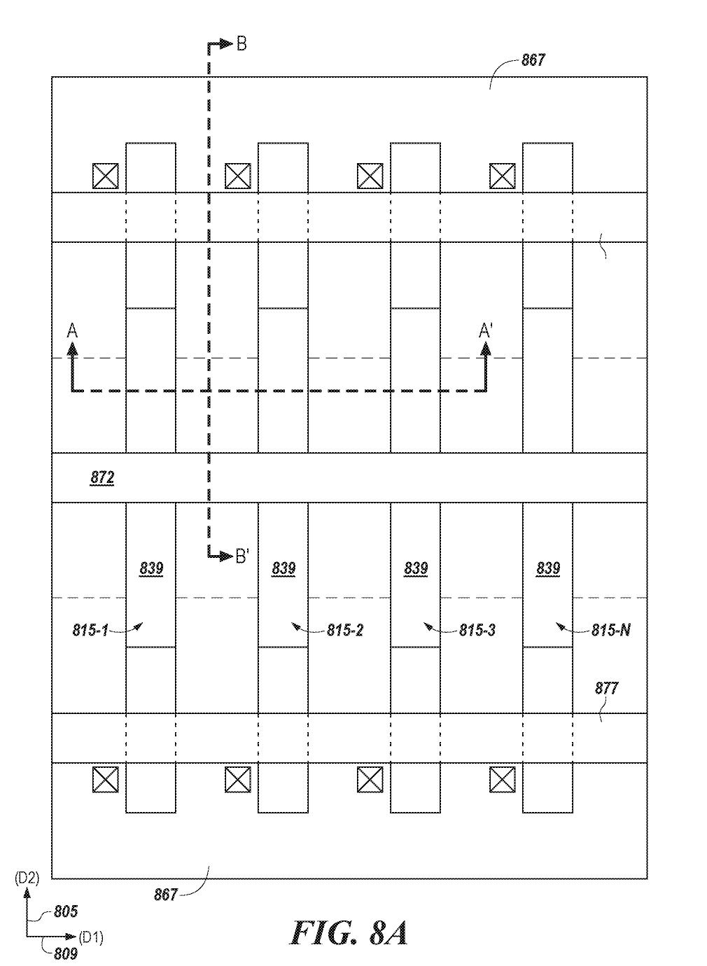

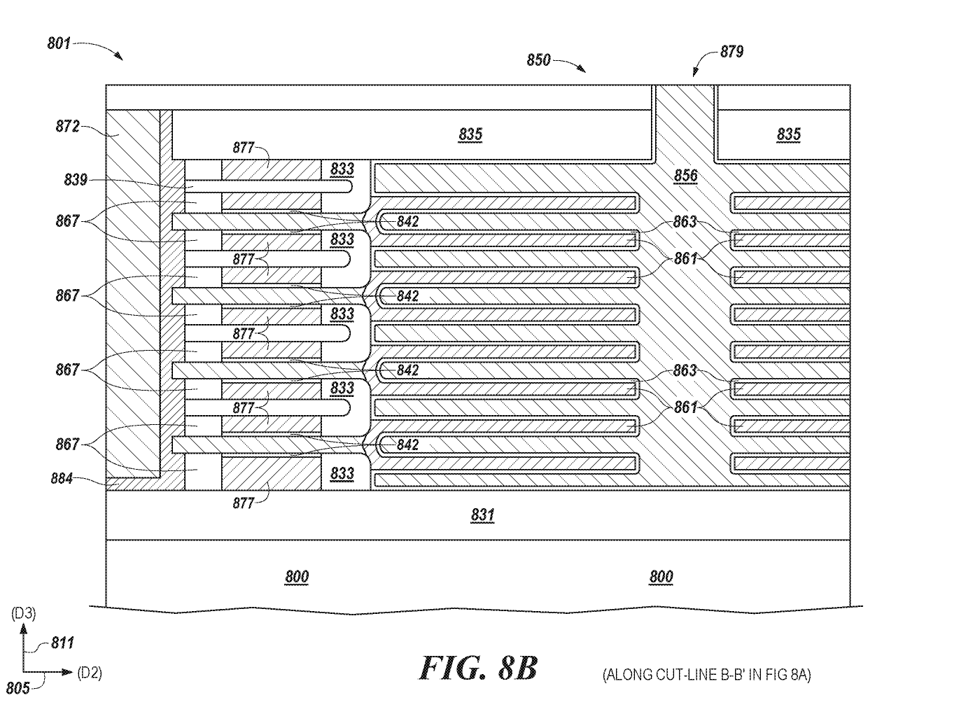

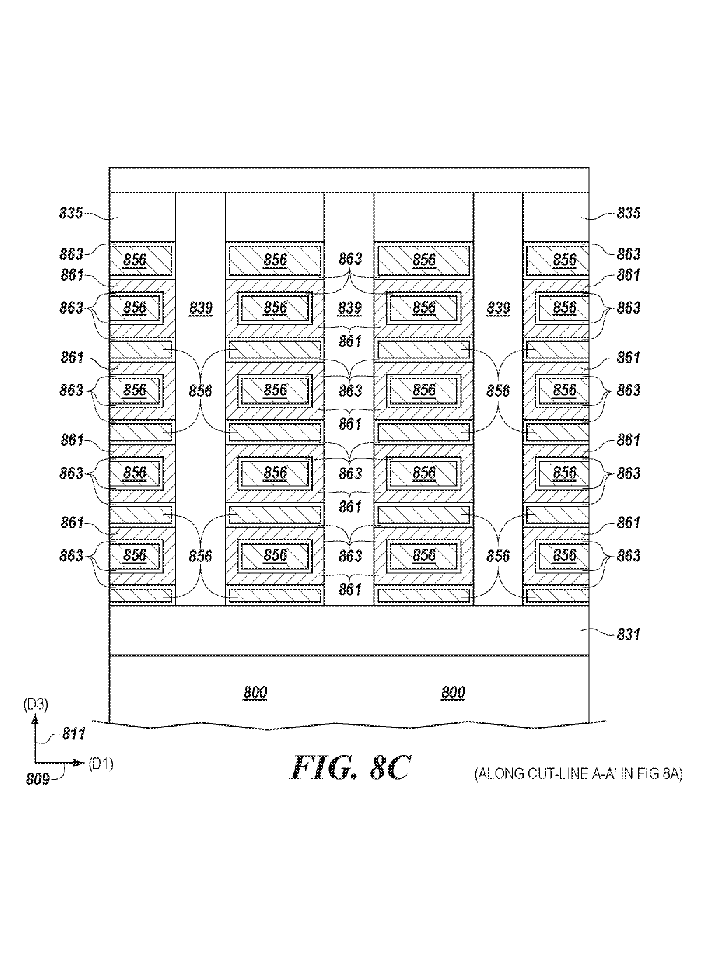

FIG. 8A illustrates an example method, at one stage of a semiconductor fabrication process, for isolating substrate in three dimensional (3D) arrays of vertically stacked memory cells, having horizontally oriented access devices and storage nodes, in accordance with a number of embodiments of the present disclosure. A vertical opening can be formed in a storage node region through the vertical stack and extending predominantly in the first horizontal direction (D1) 809.

FIG. 8B is a cross sectional view, taken along cut-line B-B’ in FIG. 8A, showing another view of the semiconductor structure at a particular time in the semiconductor fabrication process. In FIG. 8B, the one or more etchant processes can be utilized to form the storage node region 850. The storage node region 850 can include storage nodes (e.g., horizontally oriented capacitor cells) having the first electrodes 861, e.g., bottom electrodes to be coupled to source/drain regions of horizontal access devices, and second electrodes 856, e.g., top electrodes to be coupled to a common electrode plane such as a ground plane. The storage nodes are shown formed in a third horizontal opening 879, extending in second direction (D2) 805, left and right in the plane of the drawing sheet, a third distance from the vertical opening formed in the vertical stack and along an axis of orientation of the horizontal access devices and horizontal storage nodes of the arrays of vertically stacked memory cells of the three-dimensional (3D) memory. In FIG. 8B, a neighboring, horizontal access line is illustrated adjacent the second dielectric material 833, with a portion of the first conductive material 877 located above the Si material, and a portion of the first conductive material 877 located below the Si material extending in a direction inward and outward from the plane and orientation of the drawing sheet.

Additionally, as illustrated in FIG. 8B, the ILD material 867 can be removed from the vertical opening 872 and up to a vertical sidewall of the vertical opening 872, resulting in a vertical stack in the vertical opening 872 of alternating ILD material 867, dielectric material 839, ILD material 867, gate dielectric material 842, Si material, dielectric material 839, ILD fill material 867, etc.

FIG. 8C is a cross sectional view, taken along cut-line A-A’ in FIG. 8A, showing another view of the semiconductor structure at a particular time in the semiconductor fabrication process. The cross-sectional view shown in FIG. 8C is away from the plurality of separate, horizontal access lines, and shows repeating iterations of alternating layers of second electrodes 856 separated by horizontally oriented capacitor cells having first electrodes 861, e.g., bottom cell contact electrodes, cell dielectric material 863, and top, common node electrodes, to form the vertical stack on an isolation layer 831 on a semiconductor substrate 800. In the example embodiment of FIG. 8C, the first electrodes 861, e.g., bottom electrodes to be coupled to source/drain regions of horizontal access devices, and second electrodes 856 are illustrated separated by a cell dielectric material 863 extending into and out of the plane of the drawing sheet in second direction (D2) and along an axis of orientation of the horizontal access devices and horizontal storage nodes of the arrays of vertically stacked memory cells of the 3D memory. In FIG. 8C, the first dielectric material 839 is shown separating the space between neighboring horizontally oriented access devices and horizontally oriented storage nodes.

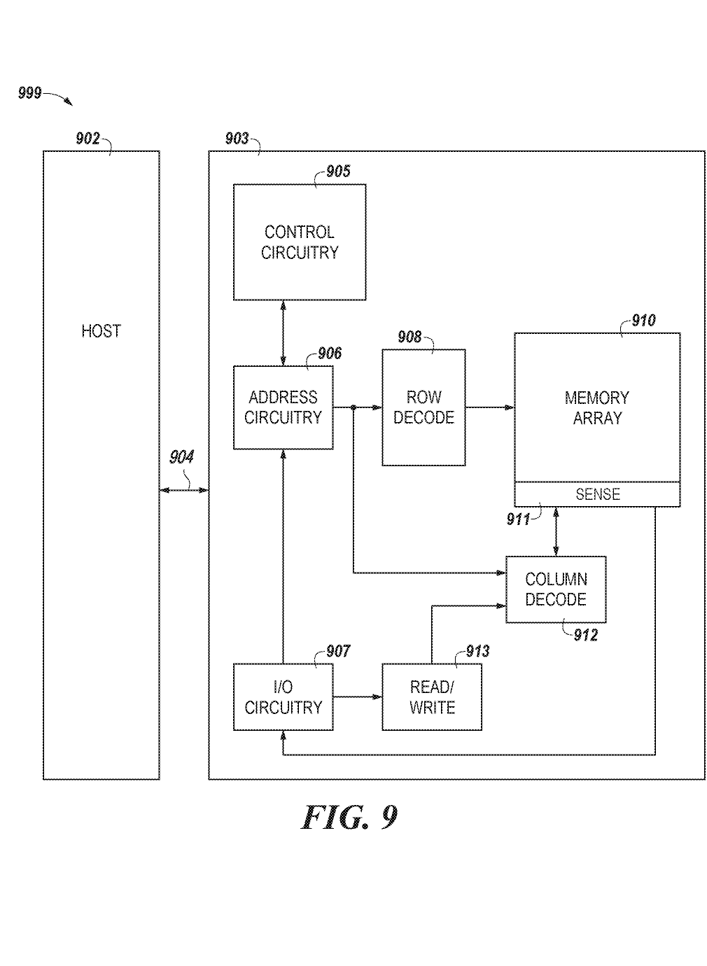

FIG. 9 is a block diagram of an apparatus in the form of a computing system 999 including a memory device 903 in accordance with a number of embodiments of the present disclosure. As used herein, a memory device 903, a memory array 910, and/or a host 902, for example, might also be separately considered an “apparatus.” According to embodiments, the memory device 903 may comprise at least one memory array 910 with a memory cell formed having a digit line and body contact, according to the embodiments described herein.

In this example, system 999 includes a host 902 coupled to memory device 903 via an interface 904. The computing system 999 can be a personal laptop computer, a desktop computer, a digital camera, a mobile telephone, a memory card reader, or an Internet-of-Things (IoT) enabled device, among various other types of systems. Host 902 can include a number of processing resources (e.g., one or more processors, microprocessors, or some other type of controlling circuitry) capable of accessing memory 903. The system 999 can include separate integrated circuits, or both the host 902 and the memory device 903 can be on the same integrated circuit. For example, the host 902 may be a system controller of a memory system comprising multiple memory devices 903, with the system controller 905 providing access to the respective memory devices 903 by another processing resource such as a central processing unit (CPU).

In the example shown in FIG. 9, the host 902 is responsible for executing an operating system (OS) and/or various applications (e.g., processes) that can be loaded thereto (e.g., from memory device 903 via controller 905). The OS and/or various applications can be loaded from the memory device 903 by providing access commands from the host 902 to the memory device 903 to access the data comprising the OS and/or the various applications. The host 902 can also access data utilized by the OS and/or various applications by providing access commands to the memory device 903 to retrieve said data utilized in the execution of the OS and/or the various applications.

For clarity, the system 999 has been simplified to focus on features with particular relevance to the present disclosure. The memory array 910 can be a DRAM array comprising at least one memory cell having a digit line and body contact formed according to the techniques described herein. For example, the memory array 910 can be an unshielded DL 4F2 array such as a 3D-DRAM memory array. The array 910 can comprise memory cells arranged in rows coupled by word lines (which may be referred to herein as access lines or select lines) and columns coupled by digit lines (which may be referred to herein as sense lines or data lines). Although a single array 910 is shown in FIG. 9, embodiments are not so limited. For instance, memory device 903 may include a number of arrays 910 (e.g., a number of banks of DRAM cells).

The memory device 903 includes address circuitry 906 to latch address signals provided over an interface 904. The interface 904 can include, for example, a physical interface employing a suitable protocol (e.g., a data bus, an address bus, and a command bus, or a combined data/address/command bus). Such protocol may be custom or proprietary, or the interface 904 may employ a standardized protocol, such as Peripheral Component Interconnect Express (PCIe), Gen-Z, CCIX, or the like. Address signals are received and decoded by a row decoder 908 and a column decoder 912 to access the memory array 910. Data can be read from memory array 910 by sensing voltage and/or current changes on the sense lines using sensing circuitry 911. The sensing circuitry 911 can comprise, for example, sense amplifiers that can read and latch a page (e.g., row) of data from the memory array 910. The I/O circuitry 907 can be used for bi-directional data communication with the host 902 over the interface 904. The read/write circuitry 913 is used to write data to the memory array 910 or read data from the memory array 910. As an example, the circuitry 913 can comprise various drivers, latch circuitry, etc.

Control circuitry 905 decodes signals provided by the host 902. The signals can be commands provided by the host 902. These signals can include chip enable signals, write enable signals, and address latch signals that are used to control operations performed on the memory array 910, including data read operations, data write operations, and data erase operations. In various embodiments, the control circuitry 905 is responsible for executing instructions from the host 902. The control circuitry 905 can comprise a state machine, a sequencer, and/or some other type of control circuitry, which may be implemented in the form of hardware, firmware, or software, or any combination of the three. In some examples, the host 902 can be a controller external to the memory device 903. For example, the host 902 can be a memory controller which is coupled to a processing resource of a computing device.

The term semiconductor can refer to, for example, a material, a wafer, or a substrate, and includes any base semiconductor structure. “Semiconductor” is to be understood as including silicon-on-sapphire (SOS) technology, silicon-on-insulator (SOI) technology, thin-film-transistor (TFT) technology, doped and undoped semiconductors, epitaxial silicon supported by a base semiconductor structure, as well as other semiconductor structures. Furthermore, when reference is made to a semiconductor in the preceding description, previous process steps may have been utilized to form regions/junctions in the base semiconductor structure, and the term semiconductor can include the underlying materials containing such regions/junctions.

The figures herein follow a numbering convention in which the first digit or digits correspond to the drawing figure number and the remaining digits identify an element or component in the drawing. Similar (e.g., the same) elements or components between different figures may be identified by the use of similar digits. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate the embodiments of the present disclosure and should not be taken in a limiting sense.

As used herein, “a number of” or a “quantity of” something can refer to one or more of such things. For example, a number of or a quantity of memory cells can refer to one or more memory cells. A “plurality” of something intends two or more. As used herein, multiple acts being performed concurrently refers to acts overlapping, at least in part, over a particular time period. As used herein, the term “coupled” may include electrically coupled, directly coupled, and/or directly connected with no intervening elements (e.g., by direct physical contact), indirectly coupled and/or connected with intervening elements, or wirelessly coupled. The term coupled may further include two or more elements that co-operate or interact with each other (e.g., as in a cause and effect relationship). An element coupled between two elements can be between the two elements and coupled to each of the two elements.

It should be recognized the term vertical accounts for variations from “exactly” vertical due to routine manufacturing, measuring, and/or assembly variations and that one of ordinary skill in the art would know what is meant by the term “perpendicular.” For example, the vertical can correspond to the z-direction. As used herein, when a particular element is “adjacent to” another element, the particular element can cover the other element, can be over the other element or lateral to the other element and/or can be in direct physical contact with the other element. Lateral to may refer to the horizontal direction (e.g., the y-direction or the x-direction) that may be perpendicular to the z-direction, for example.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

What is claimed is:

1. A three dimensional (3D) memory device, comprising:
a substrate;
an isolation layer on the substrate;
a vertical stack on the isolation layer; and
a vertical opening through the vertical stack to the isolation layer.

2. The 3D memory device of claim 1, wherein the isolation layer is formed using a wafer-to-wafer bonding.

3. The 3D memory device of claim 2, comprising a part of an etch stop layer, wherein the etch stop layer is formed on the isolation layer using the wafer-to-wafer bonding.

4. The 3D memory device of claim 1, wherein the isolation layer is configured to isolate an access device from the substrate.

5. The 3D memory device of claim 1, wherein the isolation layer includes an oxide material, an oxide nitride material, a dielectric bond material, or a dielectric copper material.

6. The 3D memory device of claim 1, wherein the vertical stack comprises a plurality of layers.

7. The 3D memory device of claim 6, wherein the plurality of layers include alternating layers of silicon germanium material and silicon material or alternating layers of epitaxial material and silicon material.

8. The 3D memory device of claim 1, comprising a multiplexor silicon layer on the vertical stack.

9. A method of forming a three dimensional (3D) memory device, comprising:
bonding a first wafer to a second wafer, wherein the first wafer includes a sacrificial substrate, an isolation layer, an etch stop layer, and a vertical stack and the second wafer includes a substrate and a bonding layer;
removing the sacrificial substrate from the first wafer to expose the vertical stack; and
removing the etch stop layer to expose the vertical stack.

10. The method of claim 9, wherein the etch stop layer includes silicon germanium carbon material, silicon germanium material, silicon carbon material, silicon phosphorus material, or silicon boron material.

11. The method of claim 9, comprising removing a portion of the vertical stack to create a vertical opening through the vertical stack to the isolation layer.

12. The method of claim 9, wherein bonding the first wafer to the second wafer includes bonding the isolation layer to the bonding layer.

13. The method of claim 9, comprising bonding the first wafer to the second wafer via oxide based fusion bonding.

14. The method of claim 9, wherein an orientation of the first wafer is rotated such that the isolation layer contacts the bonding layer.

15. The method of claim 9, comprising isolating an access device from the substrate via the isolation layer.

16. The method of claim 9, wherein the sacrificial substrate includes silicon.

17. A method of forming a three dimensional (3D) memory device, comprising:
forming an etch stop layer from a sacrificial substrate;
forming a vertical stack from the etch stop layer;
forming an isolation layer from the vertical stack;
forming a bonding layer from a substrate;
bonding the isolation layer with the bonding layer;
removing the sacrificial substrate; and
removing the etch stop layer.

18. The method of claim 17, comprising removing at least a portion of the sacrificial substrate by grinding.

19. The method of claim 17, comprising removing at least a portion of the sacrificial substrate by etching.

20. The method of claim 17, comprising removing the etch stop layer by etching.
